(19) United States
(12) Patent Application Publication
(10) Pub. No.: US 2023/0351075 A1
(43) Pub. Date: Nov. 2, 2023

(54) A SYSTEM AND METHOD FOR DESIGNING KAPLAN TURBINE-BASED ON ADVANCED BLADE DESIGN OF HYDRO-POWERED TURBINE

(71) Applicants: Siddharth Suhas Kulkarni, Birmingham (GB); Anil Ramchandra Acharya, Satara (IN); Reena Singh, Pune (IN)

(72) Inventors: Siddharth Suhas Kulkarni, Birmingham (GB); Anil Ramchandra Acharya, Satara (IN); Reena Singh, Pune (IN)

(21) Appl. No.: 18/184,384

(22) Filed: Mar. 15, 2023

(51) Int. Cl. G06F 30/27; B23P 15/02; G06Q 50/04

(52) U.S. Cl. CPC G06F 30/27; B23P 15/02; G06Q 50/04

(57) ABSTRACT

The system for designing advanced Kaplan turbine-based on advanced blade design of a hydro powered turbine comprises an EES for calculating and determining a set of parameters involved in the designing of Kaplan turbine blade; a designing user interface for designing a 3d-model of the Kaplan turbine blade; an analyzing unit for CFD analysis of the turbine models on based on the K-omega turbulent model with a Y+ of 1, wherein the turbulent model is used to ensure the near wall function of water and the rotational pressure applied on the blades thereby generating results of the analysis using CFD post and plotted on a table for the comparative study of the blade models; and a manufacturing unit for manufacturing Kaplan turbine blade based on comparative study of the blade models using a machine learning approach.

### FIELD OF THE INVENTION

The present disclosure relates to Advanced Kaplan Turbine, in more detail, a system and method for designing advanced Kaplan turbine-based on advanced blade design of a hydro powered turbine.

### BACKGROUND OF THE INVENTION

A number of previously published research papers were taken into consideration before finalizing the design of our novel turbine blades. It should be noted however that no previous study had been carried out on blade designs based on aquatic plants. Due to this reason no such research paper could be found to compare the performance of the newly designed blades properly, hence from previous studies, simple Kaplan turbine blade study was selected as a reference. Considering this reference assured us that the results obtained from the novel aquatic plant based design is much more efficient than the previous models.

In the view of the forgoing discussion, it is clearly portrayed that there is a need to have a system and method for designing advanced Kaplan turbine-based on advanced blade design of a hydro powered turbine.

### SUMMARY OF THE INVENTION

The present disclosure seeks to provide a system and method for designing advanced Kaplan turbine-based on the advanced blade design of a hydro powered turbine in shape of a unique aquatic plant.

In an embodiment, a system for designing advanced Kaplan turbine-based on advanced blade design of a hydro powered turbine is disclosed. The system includes an engineering equation solver (EES) for calculating and determining a set of parameters involved in the designing of Kaplan turbine blade.

The system further includes a designing user interface for designing a 3d-model of the Kaplan turbine blade, wherein the set of parameters are kept constant throughout the model designing to enable a constant mode of comparison between the different models of the turbine blades.

The system further includes an analyzing unit for CFD analysis of the turbine models on based on the K-omega turbulent model with a Y+ of 1, wherein the turbulent model is used to ensure the near wall function of water and the rotational pressure applied on the blades thereby generating results of the analysis using CFD post and plotted on a table for the comparative study of the blade models.

The system further includes a manufacturing unit for manufacturing Kaplan turbine blade based on comparative study of the blade models using a machine learning approach.

In an embodiment, a method for designing advanced Kaplan turbine-based on advanced blade design of a hydro powered turbine is disclosed. The method includes calculating and determining a set of parameters involved in the designing of Kaplan turbine blade using an engineering equation solver (EES).

The method further includes designing a 3d-model of the Kaplan turbine blade using a designing user interface.

The method further includes performing CFD analysis of the turbine models on based on the K-omega turbulent model with a Y+ of 1 using an analyzing unit, wherein the turbulent model is used to ensure the near wall function of water and the rotational pressure applied on the blades thereby generating results of the analysis using CFD post and plotted on a table for the comparative study of the blade models.

The method further includes manufacturing Kaplan turbine blade based on comparative study of the blade models using a machine learning approach through a manufacturing unit.

An object of the present disclosure is to provide an Advanced Kaplan Turbine (AKT) is a based on the advanced blade design of a hydro powered turbine in shape of a unique aquatic plant has been divided into 3-main categories as far as the complex design and intelligent analysis is concerned.

Another object of the present disclosure is to provide the three steps or categories those govern the analysis and design are as follows: A: Mathematical calculations on EES, B: 3d-model design on solid works, C: CFD analysis on ANSYS-16.

Another object of the present disclosure is to provide ease of understanding for the reader over how the design has been finalized and the parameters governing the equations to solve the complex mathematical model.

Another object of the present disclosure is to provide a turbine taken under consideration for invention work is Advanced Kaplan Turbine.

Yet another object of the present invention is to deliver an expeditious and cost-effective system for designing advanced Kaplan turbine-based on advanced blade design of a hydro powered turbine.

To further clarify advantages and features of the present disclosure, a more particular description of the invention will be rendered by reference to specific embodiments thereof, which is illustrated in the appended drawings. It is appreciated that these drawings depict only typical embodiments of the invention and are therefore not to be considered limiting of its scope. The invention will be described and explained with additional specificity and detail with the accompanying drawings.

### BRIEF DESCRIPTION OF FIGURES

These and other features, aspects, and advantages of the present disclosure will become better understood when the following detailed description is read with reference to the accompanying drawings in which like characters represent like parts throughout the drawings, wherein:

FIG. 1 illustrates a block diagram of a system for designing advanced Kaplan turbine-based on advanced blade design of a hydro powered turbine in accordance with an embodiment of the present disclosure;

FIG. 2 illustrates a flow chart of a method for designing advanced Kaplan turbine-based on advanced blade design of a hydro powered turbine in accordance with an embodiment of the present disclosure;

FIG. 3 illustrates sections of the blade geometry in accordance with an embodiment of the present disclosure;

FIG. 4 illustrates side view of the reference design in accordance with an embodiment of the present disclosure;

FIG. 5 illustrates orthogonal view of the reference design in accordance with an embodiment of the present disclosure;

FIG. 6 illustrates drafted design of reference model in accordance with an embodiment of the present disclosure;

FIG. 7 illustrates mesh of the complete fluid domain in accordance with an embodiment of the present disclosure;

FIG. 8 illustrates mesh of the section view in accordance with an embodiment of the present disclosure;

FIG. 9 illustrates Table 1 depicts a first reference study for comparison of the results in accordance with an embodiment of the present disclosure;

FIG. 10 illustrates Table 2 depicts a second reference study for comparison of the results in accordance with an embodiment of the present disclosure;

FIG. 11 illustrates Table 3 depicts parameter constant and acquiring the results from the program set up in EES in accordance with an embodiment of the present disclosure;

FIG. 12 illustrates Table 4 depicts set of input variables in accordance with an embodiment of the present disclosure;

FIG. 13 illustrates Table 5 depicts computational result for Novel Aquatic Plant Based Model 2 in accordance with an embodiment of the present disclosure; and

FIG. 14 illustrates Table 6 depicts computational result for Novel Aquatic Plant Based Model 3 in accordance with an embodiment of the present disclosure.

Further, skilled artisans will appreciate that elements in the drawings are illustrated for simplicity and may not have necessarily been drawn to scale. For example, the flow charts illustrate the method in terms of the most prominent steps involved to help to improve understanding of aspects of the present disclosure. Furthermore, in terms of the construction of the device, one or more components of the device may have been represented in the drawings by conventional symbols, and the drawings may show only those specific details that are pertinent to understanding the embodiments of the present disclosure so as not to obscure the drawings with details that will be readily apparent to those of ordinary skill in the art having benefit of the description herein.

### DETAILED DESCRIPTION

For the purpose of promoting an understanding of the principles of the invention, reference will now be made to the embodiment illustrated in the drawings and specific language will be used to describe the same. It will nevertheless be understood that no limitation of the scope of the invention is thereby intended, such alterations and further modifications in the illustrated system, and such further applications of the principles of the invention as illustrated therein being contemplated as would normally occur to one skilled in the art to which the invention relates.

It will be understood by those skilled in the art that the foregoing general description and the following detailed description are exemplary and explanatory of the invention and are not intended to be restrictive thereof.

Reference throughout this specification to “an aspect”, “another aspect” or similar language means that a particular feature, structure, or characteristic described in connection with the embodiment is included in at least one embodiment of the present disclosure. Thus, appearances of the phrase “in an embodiment”, “in another embodiment” and similar language throughout this specification may, but do not necessarily, all refer to the same embodiment.

The terms “comprise”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components.

Unless otherwise defined, all technical and scientific terms used herein have the same meaning as commonly understood by one of ordinary skill in the art to which this invention belongs. The system, methods, and examples provided herein are illustrative only and not intended to be limiting.

Embodiments of the present disclosure will be described below in detail with reference to the accompanying drawings.

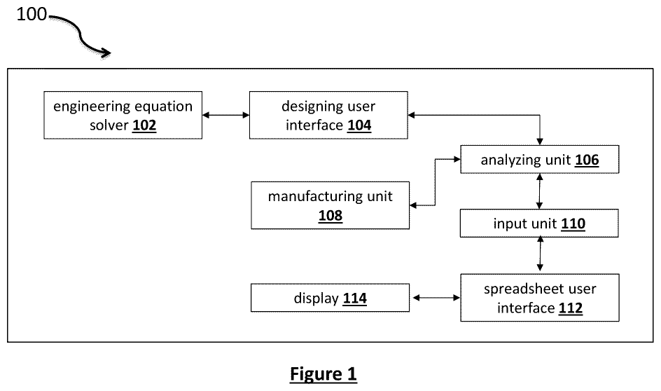

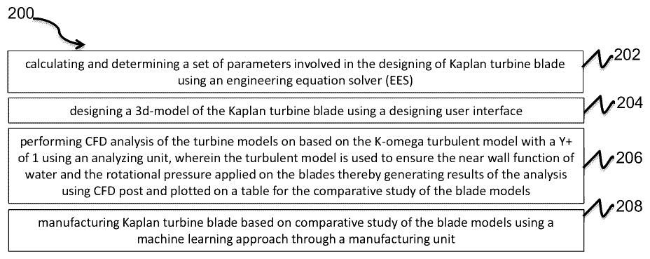

Referring to FIG. 1, a block diagram of a system for designing advanced Kaplan turbine-based on advanced blade design of a hydro powered turbine is illustrated in accordance with an embodiment of the present disclosure. the system 100 includes an engineering equation solver (EES) 102 for calculating and determining a set of parameters involved in the designing of Kaplan turbine blade.

In an embodiment, a designing user interface 104 is coupled to the engineering equation solver 102 for designing a 3d-model of the Kaplan turbine blade, wherein the set of parameters are kept constant throughout the model designing to enable a constant mode of comparison between the different models of the turbine blades.

In an embodiment, an analyzing unit 106 is coupled to the designing user interface 104 for CFD analysis of the turbine models on based on the K-omega turbulent model with a Y+ of 1, wherein the turbulent model is used to ensure the near wall function of water and the rotational pressure applied on the blades thereby generating results of the analysis using CFD post and plotted on a table for the comparative study of the blade models.

In an embodiment, a manufacturing unit 108 is coupled to the analyzing unit 106 for manufacturing Kaplan turbine blade based on comparative study of the blade models using a machine learning approach.

In another embodiment, the set of parameters are selected from a group of flow rate, design head, generator efficiency, hydraulic efficiency, mechanical efficiency, coefficient of specific speed, and specific weight of water.

In another embodiment, the flow rate and the head are kept low in order to simulate the models as per the working conditions of a Kaplan turbine, wherein the hydraulic, mechanical and generator efficiencies are taken into account to achieve a more realistic value for the power obtained from these models.

In another embodiment, the analyzing unit 106 for comparative study comprises an input unit 110 for obtaining data from the analysis and set up in an spreadsheet user interface 112 to obtain the desired graphical representation of the comparative study, wherein the study includes the graphical representation of how the efficiency and power of the blades vary with the flow rate.

In one embodiment, a display 114 is connected to the spreadsheet user interface for showing graphs to show that the best model design that gives the maximum computational efficiency and power.

In another embodiment, a pressure ratio variation is plotted with respected to the blade torque, rotation and the last plot is made for the variation in the power of the blades with respect to the flow rate of the water, wherein the Flow rate depends on a few factors like height of the water source and the turbulence it has.

FIG. 2 illustrates a flow chart of a method for designing advanced Kaplan turbine-based on advanced blade design of a hydro powered turbine in accordance with an embodiment of the present disclosure. At step 202, method 200 includes calculating and determining a set of parameters involved in the designing of Kaplan turbine blade using an engineering equation solver (EES) 102.

At step 204, method 200 includes designing a 3d-model of the Kaplan turbine blade using a designing user interface 104.

At step 206, method 200 includes performing CFD analysis of the turbine models on based on the K-omega turbulent model with a Y+ of 1 using an analyzing unit 106, wherein the turbulent model is used to ensure the near wall function of water and the rotational pressure applied on the blades thereby generating results of the analysis using CFD post and plotted on a table for the comparative study of the blade models.

At step 208, method 200 includes manufacturing Kaplan turbine blade based on comparative study of the blade models using a machine learning approach through a manufacturing unit 108.

In another embodiment, the set of parameters are kept constant throughout the model designing to enable a constant mode of comparison between the different models of the turbine blades.

In another embodiment, comparative study comprising steps of obtaining data from the analysis and setting up in a spreadsheet user interface to obtain the desired graphical representation of the comparative study, wherein the study includes the graphical representation of how the efficiency and power of the blades vary with the flow rate. Then, showing graphs on a display to show that the best model design that gives the maximum computational efficiency and power, wherein a pressure ratio variation is plotted with respected to the blade torque, rotation and the last plot is made for the variation in the power of the blades with respect to the flow rate of the water, wherein the Flow rate depends on a few factors like height of the water source and the turbulence it has.

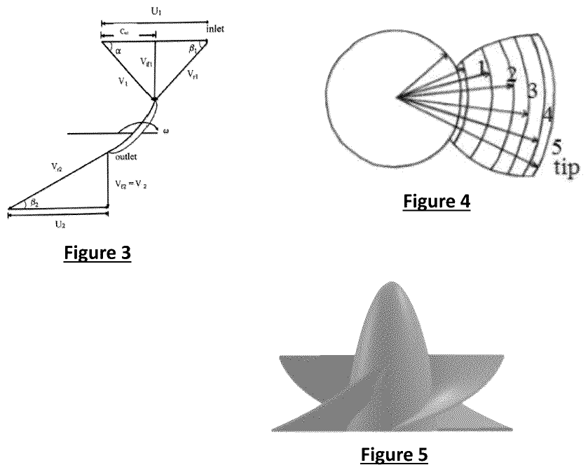

FIG. 3 illustrates sections of the blade geometry in accordance with an embodiment of the present disclosure.

FIG. 4 illustrates side view of the reference design in accordance with an embodiment of the present disclosure.

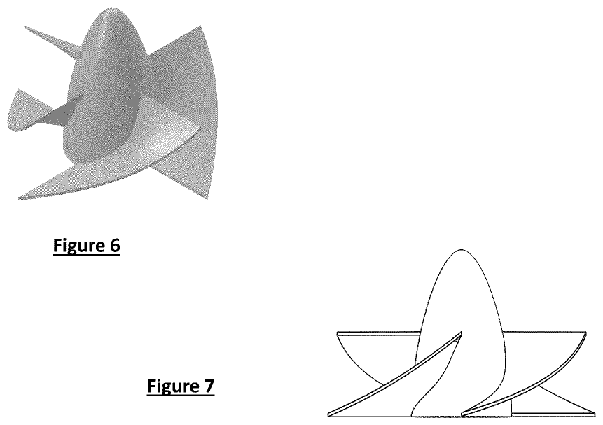

FIG. 5 illustrates orthogonal view of the reference design in accordance with an embodiment of the present disclosure.

FIG. 6 illustrates drafted design of reference model in accordance with an embodiment of the present disclosure.

FIG. 7 illustrates mesh of the complete fluid domain in accordance with an embodiment of the present disclosure.

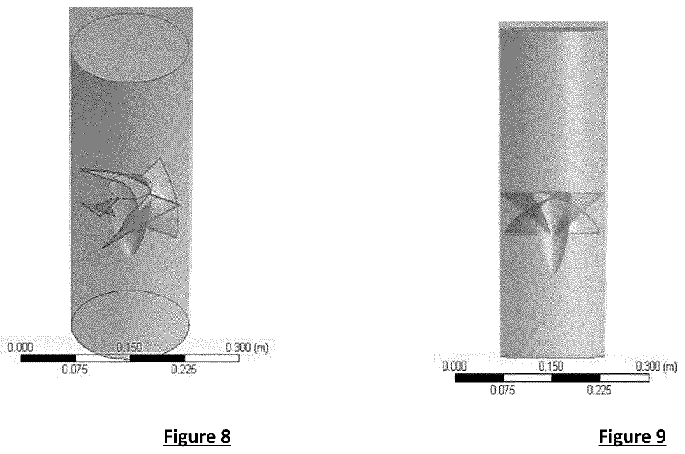

FIG. 8 illustrates mesh of the section view in accordance with an embodiment of the present disclosure.

FIG. 9 illustrates Table 1 depicts a first reference study for comparison of the results in accordance with an embodiment of the present disclosure. The input variables are setup with values provided in table 1. Based on the input provided and the design calculations the following theoretical results are obtained from the EES program calculations.

The data has been recorded for all the five sections on the turbine blades. The theoretical efficiency came out to be 92.45% along with power output as 15 KW. The next step towards the computational test of the theoretical model will be to construct the geometry on solidworks using the similar parameters and then testing the model on ANSYS CFX for the calculation of computational results.

### Solidworks Design of the Reference Model:

Based on the data extracted from the mathematical calculations a reference model is designed on solidworks and the following images show the different views of the reference model that is used to match the values of our novel design. The models are constructed on solidworks software as part designs and it has a thickness of 2 mm. the thickness is taken as an arbitrary measurement as the analysis is only based on CFD and not FEA

### Theoretical Calculations:

A number of previously published research papers are taken into consideration before finalizing the design of our novel turbine blades. It should be noted however that no previous study had been carried out on blade designs based on aquatic plants.

Due to this reason no such research paper could be found to compare the performance of the newly designed blades properly, hence from previous studies, simple Kaplan turbine blade study is selected as a reference. Considering this reference assured us that the results obtained from the novel aquatic plant based design is much more efficient than the previous models. The reference model is redesigned on solidworks and the theoretical results are obtained through the EES program that had been previously setup for the calculations.

FIG. 10 illustrates Table 2 depicts a second reference study for comparison of the results in accordance with an embodiment of the present disclosure. The input variables are setup with values provided in table 2. Based on the input provided and the design calculations the following theoretical results are obtained from the EES program calculations.

The data has been recorded for all the five sections on the turbine blades. The theoretical efficiency came out to be 92.45% along with power output as 15 KW. The next step towards the computational test of the theoretical model will be to construct the geometry on solidworks using the similar parameters and then testing the model on ANSYS CFX for the calculation of computational results.

### Solidworks Design of the Reference Model:

Based on the data extracted from the mathematical calculations a reference model is designed on solidworks and the following images show the different views of the reference model that is used to match the values of our novel design. The models are constructed on solidworks software as part designs and it has a thickness of 2 mm. the thickness is taken as an arbitrary measurement as the analysis is only based on CFD and not FEA.

### CFD Analysis On the Reference Model:

As mentioned above in the project briefing the CFD analysis of the models is carried out in ANSYS CFX. The purpose of choosing this software is because it gives more accurate results for the computational calculations of the rotating components. Following is the briefing about the fluid domain produced the meshing on the model and the results obtained from the CFD simulation.

### Modelling:

the blade model designed in solidworks is converted to the design modular file that could be read by ANSYS. A fluid domain has been created around the body of the blade so that the fluid (water) can pass over the blades.

### Meshing of the Model:

the meshing of the design is carried out in ANSYS mesh modular. This is a robust software for the meshing of the models. The mesh size is kept fine and a Y+ of 1 is considered near the walls of the blade. An inflation is created near the blade surface to capture the boundary layer. The following images show the mesh generated for the model.

### Results of the Analysis:

as highlighted above the analysis is carried out in ANSYS CFX using the conditions in table 2. The turbulent model used is K-epsilon due to its better functioning under rotational bodies. A residual limit of 10⁻⁴ is considered during the analysis and the solution is run until the results did not converge. The results of the analysis are shown as under. All the further analysis those have been done on the other models have been treated with the same set of limits and conditions.

The CFD results gave the total blade efficiency to be 54.7% with a power output of 8.806 KW, this difference in the theoretical and computational results is common due to the variation in the limits and assumptions.

Novel Aquatic Plant Based Model 1:

The inspiration for the new blade design based on an aquatic plant is taken from the sea weed. Sea weed is the most commonly found sea plant in the world and its aerodynamic and streamlined body inspired us to choose it as the plant of inspiration.

The mathematical model will be solved with the angles taken from the seaweed profile and will be used in our already set mathematical equations to obtain the parameters of the turbine.

For the blade design, one leaf of the sea weed is taken and wrapped around the center shaft to achieve a spiral configuration. However, here to achieve the best results from our model the spiral chosen is configured according to the golden ratio, or more particularly the Fibonacci spiral.

This type of spiral configuration is shown in the figure below and only the first three quarters of this spiral are considered for the designing of our turbine blades. This configuration helps achieve the best aspect ratio for the flow of the fluid from over the blades of the model. Thereby increasing the efficiency of the turbine effectively.

A simple Fibonacci spiral can either be created using a spiral or a golden triangle (isosceles triangle with angle at the vertex equal to π/5. The spiral is obtained that can be called triangular golden spiral; when this spiral is turned by 3π/5, it is enlarged by a factor j; therefore, it is an approximation of the logarithmic spiral

$$ρ = a {φ}^{\frac{θ}{3 π / 5}} ;$$

the enlargement factor at each turn is Ω^{10/3}≅5 and the polar tangential angle is about 76°. This method is adapted in the designing process of the turbine blades. However, it should be noted that the Fibonacci spiral equation is kept constant for all the 3 models. The purpose of keeping it constant is to achieve comparable results. The blade angles are altered to achieve a greater efficiency from the blades.

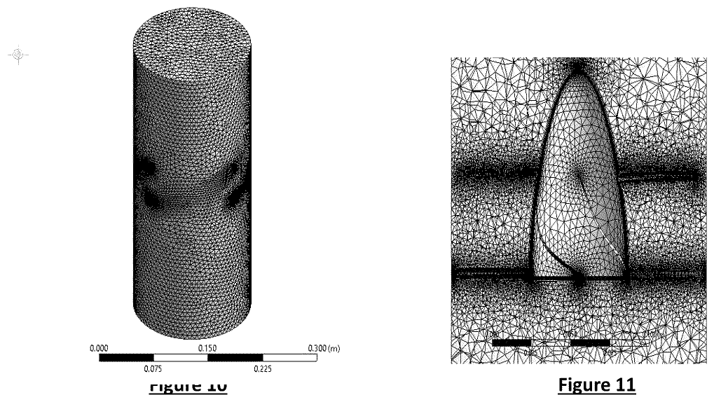

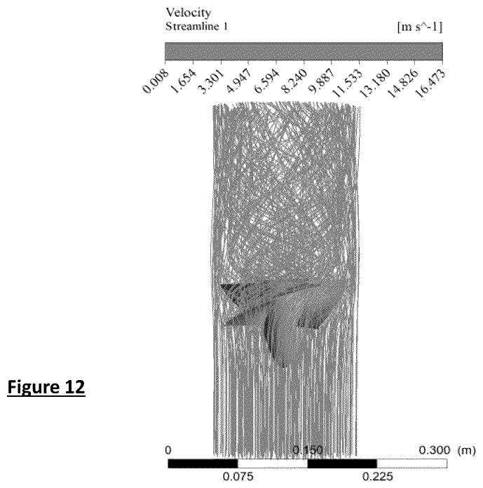

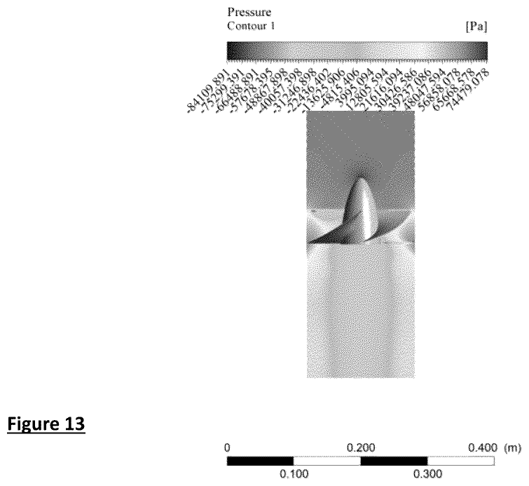

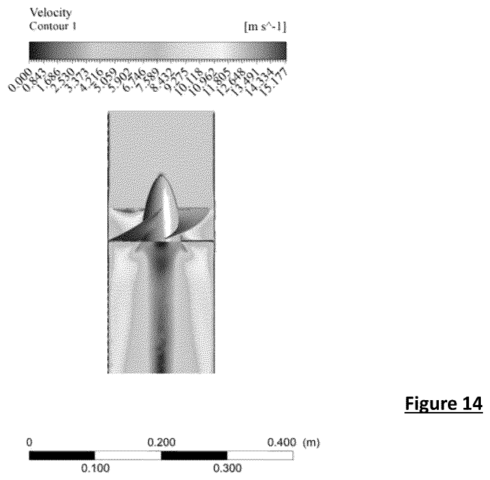

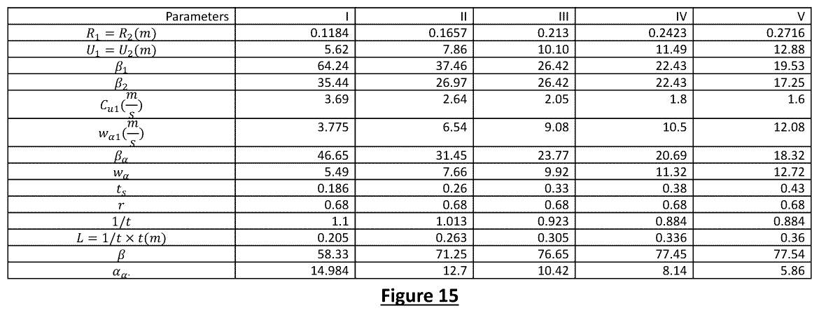

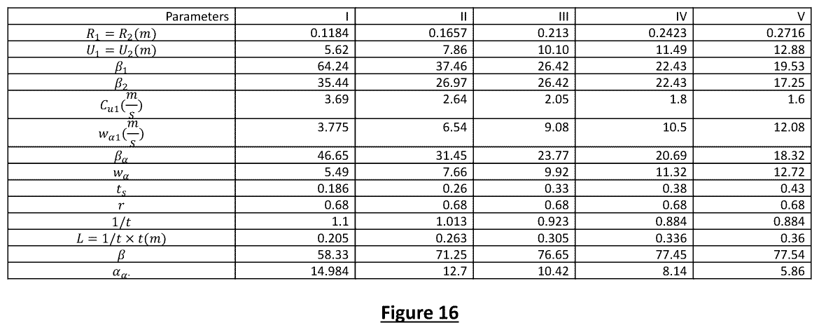

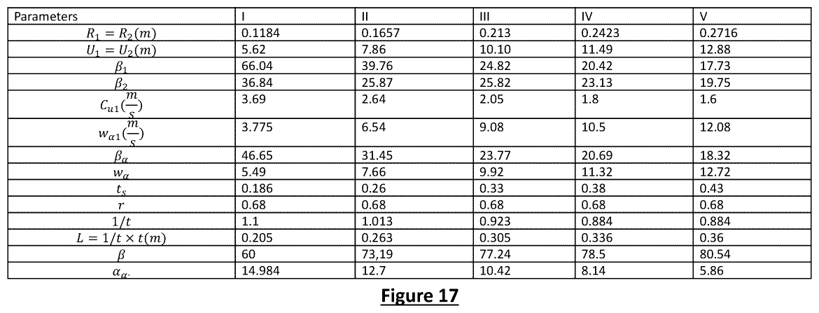

FIG. 11 illustrates Table 3 depicts parameter constant and acquiring the results from the program set up in EES in accordance with an embodiment of the present disclosure.

### Theoretical Calculations:

The theoretical calculations for the first model of the aquatic plant based blades are done using the program set in EES. The Fibonacci spiral will be set constant for all the 3 novel designs. The only variation in the blade design will be the angle at which the blades are fitted. Through theoretical knowledge Kaplan turbine works best at an angle of 65 from the horizontal.

The first model is designed using the same design characteristics similar to the reference model, the only addition made in the design is of the golden ratio spiral that is used for the profile of the turbine blades. Keeping the other parameter constant and acquiring the results from the program set up in EES the following results are obtained from the calculations shown in the following table. Due to the use of the Fibonacci spiral a little impact

Is made on the total angle of the blade β. It should also be noted that the radius of the blades for all sections and the initial velocities will be kept constant for a comparative analysis at the end.

Through EES calculations the theoretical efficiency came out to be 92.95% along with power output as 15.081 KW. The results showed that the golden spiral did effect the theoretical efficiency to some extent. For the new models the blade angle β is further modified to check for the results of efficiency.

The first model will now be checked using a computational model and the results will be compared at the end using graphs for a clearer picture of the increase in efficiency and power output.

The research based on the novel blade design of a hydro powered turbine in shape of an aquatic plant has been divided into 3 main categories as far as the design and analysis is concerned. The three steps or categories those govern the analysis and design are as follows:

1 Mathematical calculations on EES

2 3d-model design on solid works

3 CFD analysis on ANSYS 16.0

The methodology has been divided into these categories for the ease of understanding for the reader over how the design has been finalized and the parameters governing the equations to solve the mathematical model. The turbine taken under consideration for this research work is KAPLAN TURBINE. The purpose of selecting a Kaplan turbine is based on its efficient application in presence of low head and high flow rate conditions. The turbine has been designed so as to work in the high flow rate conditions often found in the rivers or fast flowing streams.

Kaplan turbine is an axial reaction turbine that is mathematically based on the velocity triangles and governing equations for the power generation and the efficiency obtained. However, solving these equations without the aid of a proper software becomes very difficult. Therefore, for the calculations and determination of the parameters involved in the blade design are solved using the software EES-engineering equation solver 102.

EES is a robust software for calculation of all kind of mathematical equations and parametric calculations. The mathematical equations those govern the blade design are set as inputs in EES software and the equations are solved using simultaneous formulation. The set of input variables are also defined in the software those are displayed in the table below.

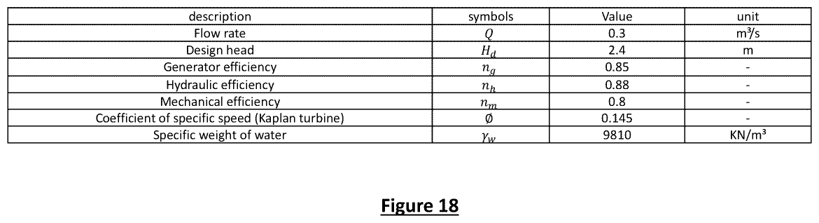

FIG. 12 illustrates Table 4 depicts set of input variables in accordance with an embodiment of the present disclosure. These input variables are kept constant throughout the research to enable a constant mode of comparison between the different models of the turbine blades. The flow rate and the head are kept low in order to simulate the models as per the working conditions of a Kaplan turbine. The hydraulic, mechanical and generator efficiencies are taken into account to achieve a more realistic value for the power obtained from these models.

These efficiencies can be neglected to achieve an ideal power output from the turbine. The blade characteristics obtained from the calculations of the mathematical model are then used to design the blade geometries in solidworks using splines and surfaces to achieve the shape of the blade. The thickness of the blades is to be kept constant for all the models in order to have a reference point for the comparative analysis.

However, a streamlined body of the blades based on the shape of an aquatic plant has been considered for comparative study.

The next step towards the completion of the research is the CFD analysis of the turbine models on ANSYS 16.0, based on the K-omega turbulent model with a Y+ of 1. This turbulent model is used to ensure the near wall function of water and the rotational pressure applied on the blades. The results of the analysis are then obtained through CFD post and plotted using EXCEL software for the comparative study of the blade models.

### Mathematical Calculation of the Turbine Blade:

All the governing equations and formulas for the mathematical calculation of the turbine blade are mentioned below. The equations, as explained before, will be solved using the software EES. This software will provide us tabulated results of all the variables those are unknown in the given mathematical equations. And using the set of obtained values blade geometry will be designed and tested on ANSYS for the computational results.

The Euler turbomachinery equation will give us the power output:

p=\dot{m}Ω(r₂v₂−r₁v₁)

The required shaft power can be obtained from the following equation:

$$B P = \frac{generator output}{{n}_{g} \times {n}_{m}}$$

The specific speed can be calculated from the following equation:

$${N}_{s} = \frac{885.5}{{H}_{d}^{0.25}}$$

Speed of the turbine can be calculated form the equation:

$$N = \frac{{N}_{S} \times {H}_{d}^{1.25}}{\sqrt{P}}$$

The runner discharge diameter and the hub diameter can be calculated from the following equation:

$$D = \frac{84.5 \times ∅ \times \sqrt{{H}_{d}}}{N}$$

$$Here ;$$

$$∅ = 0. 0242 \times {N}_{s}^{2 / 3}$$

Given under, are all the equations used to fully define the velocity triangle of the blades:

Guide vane angle can be calculated from the following equation:

$$tan ∝ = \frac{{v}_{f}}{{c}_{u 1}}$$

The number of guide blades can be formulated by:

Z=¼\sqrt{D}+5

The spacing of the blades is calculated using the equation:

$${t}_{s} = \frac{2 r π}{z}$$

The blade inlet and outlet angles can be formulated from:

$$tan {β}_{1} = \frac{{v}_{f 1}}{{u}_{1} - {c}_{u 11}}$$

$$tan {β}_{2} = \frac{{v}_{f 1}}{{u}_{1}}$$

The circulation at the outlet can also be formulated using the equation:

circulation=t(Cᵤ₁−Cᵤ₂)

For proper blade geometry specification, the blade geometry has been divided into 5 segments, in order to achieve the proper design characteristics.

$${r}_{1} = \frac{d}{2} + 0.0 \; 15 D \qquad segment I$$

$${r}_{2} = \frac{{r}_{3} - {r}_{1}}{2} + {r}_{1} \qquad segment II$$

$${r}_{3} = \frac{d}{2} \sqrt{( 1} + {D}_{d}^{2} ) / 2 \qquad segment III$$

$${r}_{4} = \frac{{r}_{5} - {r}_{3}}{2} + {r}_{3} \qquad segment IV$$

$${r}_{5} = \frac{D}{2} + 0.015 D \qquad segment V$$

For the power and efficiency calculations the following formulas are used to determine the forces acting on the blade:

Axial force can be tabulated from the following formula:

Fₐ=gpH_{d}A_{b}

Tangential force can be calculated from the following:

$${F}_{t} = \frac{p}{2 π \times N \times z \times {r}_{c p}}$$

The resultant force for both the axial and tangential force is given by:

Fᵣ=\sqrt{Fₐ}²+Fₜ²

Machine efficiency is given by the following equation:

### Equations Setup on EES:

$$n = \frac{p}{\dot{m} g Δ {H}_{a c t u a l}}$$

Now as all the equations have been noted, the equations will be converted to coding for EES solver. The purpose to convert the equations to codes is so that they can easily be read by the program set up in EES. The following image shows the equations set up in EES and are solved in the software and later the results are finalized in form of tables.

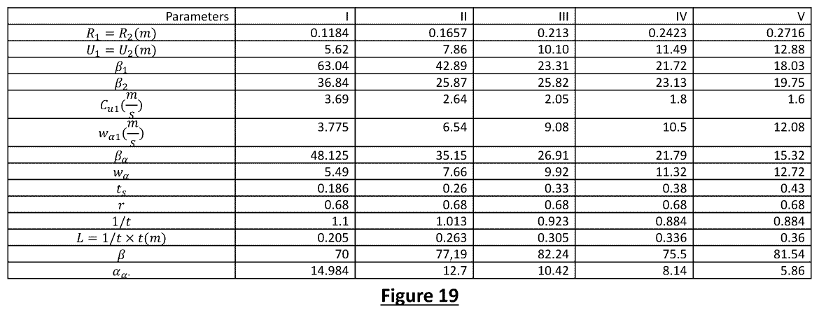

FIG. 13 illustrates Table 5 depicts computational result for Novel Aquatic Plant Based Model 2 in accordance with an embodiment of the present disclosure.

### Theoretical Calculations:

Considering the same formulation and characteristics of the blade spline, the theoretical calculations are made using the EES equations program with the only variation of the blade angle β to 70 in the input parameters. The results of the calculations are shown in the following table that has been auto generated using the EES software.

The theoretical calculations show that the theoretical efficiency came out to be 93.55% along with power output as 15.17 KW. Taking into account that modifying the Blade angles did effect the efficiency of the turbine, for the last design, the blade angle is increased to check for the variation in the results. The second model of the blade design is made in solidworks and is also checked using CFX for the computational results.

### Solidworks Design of the Reference Model:

Based on the previous model design that is created on solidworks. The only modification that has been made in this second model is the variation in the blade angle of the rotor. The blade angle has now been kept as 70′ as mentioned in the theoretical calculations. On the bases of the new blade angle the model will be tested for CFD and checked if the efficiency increases like shown in the theoretical calculations or not.

The models look nearly similar because all the other parameters are kept constant and only the blade angles have been modified. The greater tilt of the blade angles has been marked on the bottom portion of the blades.

### CFD Analysis On the Novel Model 2:

Under similar conditions for the analysis the NOVEL model 2 is tested.

### Modelling:

the fluid domain model for the first model is shown below.

Meshing of the model:

the following images show the meshing done on the first NOVEL design.

### Results:

based on the analysis the following results are obtained under similar set of conditions. The computational results showed that the efficiency of the model came out to be 56.01% with a power output of 9.0176 KW.

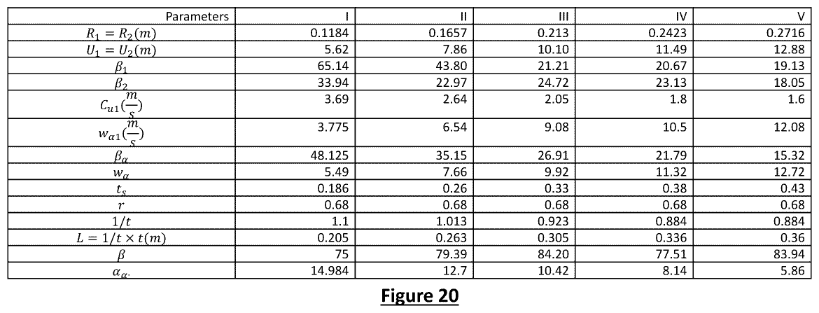

FIG. 14 illustrates Table 6 depicts computational result for Novel Aquatic Plant Based Model 3 in accordance with an embodiment of the present disclosure.

### Theoretical Calculations:

Considering the same formulation and characteristics of the blade spline, the theoretical calculations are made using the EES equations program with the only variation of the blade angle β to 75′ for the last design in the input parameters. The results of the calculations are shown in the following table that has been auto generated using the EES software.

The theoretical calculations show that the theoretical efficiency came out to be 93.89% along with power output as 15.23 KW. Further changing the blade angle showed a very little effect on the turbine efficiency. This shows that further increasing the angle can even seize the improvement in the turbine efficiency and can result in the negative impact. The final model will now be tested using the computational procedures and the results will be used for comparative study.

It should be noted here that the thecretical calculations are based on a number of assumptions and simplifications, therefore sometimes the results can be too unrealistic. Hence testing the model using computational techniques ensure the actual performance of the design. The efficiency that is expected to be achieved from all the 3 novel designs using computational methods will be greater than 55 and less than 70. The results obtained will give a better demonstration of the performance.

### Solidworks Design of the Reference Model:

Based on the results of the previous 2 models and their analysis, it is observed that increasing the blade angle does increase the efficiency of the turbine. However, it is also known through theoretical observation that increasing the blade angle a lot more will have an adverse effect on the performance.

Therefore, for the last test the blade angle is only kept 75′ and the results are noted after testing the model designed on solidworks. Once again it should be noted that the design looks similar as only the blade angle is modified for the parametric study.

### CFD Analysis on the Novel Model 3:

Under similar conditions for the analysis the NOVEL model 3 is tested.

### Modelling:

the fluid domain model for the first model is shown below

### Meshing of the Model:

the following images show the meshing done on the first NOVEL design.

Results: based on the analysis the following results are obtained under similar set of conditions. The computational results showed that the efficiency of the model came out to be 56.9% with a power output of 9.1609 KW.

### Comparative Study on the 4 Blade Models:

The data is obtained from the analysis and is set up in excel to obtained the desired graphical representation of the comparative study. The study includes the graphical representation of how the efficiency and power of the blades vary with the flow rate. The graphs show that the best model design is model 4 that gives the maximum computational efficiency and power. The graphs are plotted as under.

The comparative efficiency chart shows that as the models are modified the efficiency gradually increased. However as explained earlier the efficiency of the model 2 and 3 is nearly the same, it showed that no further change in angle will increase efficiency, it might even put a negative impact.

Next a pressure ratio variation is plotted with respected to the blade torque, rotation. The data is obtained from CFD post and the results are plotted using excel document.

The last plot is made for the variation in the power of the blades with respect to the flow rate of the water. Flow rate depends on a few factors like height of the water source and the turbulence it has.

However, it is directly proportional to the flow rate and conceptually too it can be proven that increasing the flow rate on the blades will push them faster and will generate more power. The following graph shows the variation of power w.r.t flow rate.

The system provides a Advanced Kaplan Turbine (AKT) is a based on the advanced blade design of a hydro powered turbine in shape of a unique aquatic plant has been divided into 3-main categories as far as the complex design and intelligent analysis is concerned. The system provides the three steps or categories those govern the analysis and design are as follows: A: Mathematical calculations on EES, B: 3d-model design on solid works, C: CFD analysis on ANSYS-16. The methodology has been divided into these categories for the ease of understanding for the reader over how the design has been finalized and the parameters governing the equations to solve the complex mathematical model. The system provides a turbine taken under consideration for invention work is Advanced Kaplan Turbine. The purpose of selecting a AKT is based on its efficient application in presence of low head and very high flow rate conditions. The turbine has been advanced designed so as to work in the high flow rate conditions often found in the rivers or fast flowing streams. The AKT is an axial reaction turbine that is mathematically based on the velocity triangles and governing equations for the power generation and the efficiency obtained. The system provides a solving these equations without the aid of a proper software becomes very difficult. Therefore, for the calculations and determination of the parameters involved in the blade design are solved using the software EES-Engineering equation solver 102. EES is a robust software for calculation of all kind of mathematical equations and parametric calculations. The system provides a mathematical equation those govern the blade design are set as inputs in EES software and the equations are solved using simultaneous formulation. The Advanced Kaplan Turbine (AKT) is a based on the advanced blade design of a hydro powered turbine in shape of a unique aquatic plant has been divided into 3-main categories as far as the complex design and intelligent analysis is concerned. The three steps or categories those govern the analysis and design are as follows: A: Mathematical calculations on EES, B: 3d-model design on solid works, C: CFD analysis on ANSYS-16. The methodology has been divided into these categories for the ease of understanding for the reader over how the design has been finalized and the parameters governing the equations to solve the complex mathematical model. The turbine taken under consideration for invention work is Advanced Kaplan Turbine. The purpose of selecting a AKT is based on its efficient application in presence of low head and very high flow rate conditions. The turbine has been advanced designed so as to work in the high flow rate conditions often found in the rivers or fast flowing streams. AKT is an axial reaction turbine that is mathematically based on the velocity triangles and governing equations for the power generation and the efficiency obtained. However, solving these equations without the aid of a proper software becomes very difficult. Therefore, for the calculations and determination of the parameters involved in the blade design are solved using the software EES-Engineering equation solver 102. EES is a robust software for calculation of all kind of mathematical equations and parametric calculations. The mathematical equations those govern the blade design are set as inputs in EES software and the equations are solved using simultaneous formulation.

The Advanced Kaplan Turbine (AKT) is a based on the advanced blade design of a hydro powered turbine in shape of a unique aquatic plant has been divided into 3-main categories as far as the complex design and intelligent analysis is concerned and also the three steps or categories those govern the analysis and design are as follows: A: Mathematical calculations on EES, B: 3d- model design on solid works, C: CFD analysis on ANSYS-16. The methodology has been divided into these categories for the ease of understanding for the reader over how the design has been finalized and the parameters governing the equations to solve the complex mathematical model. The turbine taken under consideration for invention work is Advanced Kaplan Turbine. The purpose of selecting a AKT is based on its efficient application in presence of low head and very high flow rate conditions. The turbine has been advanced designed so as to work in the high flow rate conditions often found in the rivers or fast flowing streams. The AKT is an axial reaction turbine that is mathematically based on the velocity triangles and governing equations for the power generation and the efficiency obtained. However, solving these equations without the aid of a proper software becomes very difficult. Therefore, for the calculations and determination of the parameters involved in the blade design are solved using the software EES-Engineering equation solver 102. The EES is a robust software for calculation of all kind of mathematical equations and parametric calculations. The mathematical equations those govern the blade design are set as inputs in EES software and the equations are solved using simultaneous formulation.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component of any or all the claims.

1. A system for designing advanced Kaplan turbine-based on advanced blade design of a hydro powered turbine, the system comprises:
an engineering equation solver (EES) for calculating and determining a set of parameters involved in the designing of Kaplan turbine blade;
a designing user interface for designing a 3d-model of the Kaplan turbine blade, wherein the set of parameters are kept constant throughout the model designing to enable a constant mode of comparison between the different models of the turbine blades;
an analyzing unit for CFD analysis of the turbine models on based on the K-omega turbulent model with a Y+ of 1, wherein the turbulent model is used to ensure the near wall function of water and the rotational pressure applied on the blades thereby generating results of the analysis using CFD post and plotted on a table for the comparative study of the blade models; and
a manufacturing unit for manufacturing Kaplan turbine blade based on comparative study of the blade models using a machine learning approach.

2. The system as claimed in claim 1, wherein the set of parameters are selected from a group of flow rate, design head, generator efficiency, hydraulic efficiency, mechanical efficiency, coefficient of specific speed, and specific weight of water.

3. The system as claimed in claim 1, wherein the flow rate and the head are kept low in order to simulate the models as per the working conditions of a Kaplan turbine, wherein the hydraulic, mechanical and generator efficiencies are taken into account to achieve a more realistic value for the power obtained from these models.

4. The system as claimed in claim 1, wherein the analyzing unit for comparative study comprises:
an input unit for obtaining data from the analysis and set up in a spreadsheet user interface to obtain the desired graphical representation of the comparative study, wherein the study includes the graphical representation of how the efficiency and power of the blades vary with the flow rate; and
a display for showing graphs to show that the best model design that gives the maximum computational efficiency and power.

5. The system as claimed in claim 4, wherein a pressure ratio variation is plotted with respected to the blade torque, rotation and the last plot is made for the variation in the power of the blades with respect to the flow rate of the water, wherein the Flow rate depends on a few factors like height of the water source and the turbulence it has.

6. A method for designing advanced Kaplan turbine-based on advanced blade design of a hydro powered turbine, the method comprises:
calculating and determining a set of parameters involved in the designing of Kaplan turbine blade using an engineering equation solver (EES);
designing a 3d-model of the Kaplan turbine blade using a designing user interface;
performing CFD analysis of the turbine models on based on the K-omega turbulent model with a Y+ of 1 using an analyzing unit, wherein the turbulent model is used to ensure the near wall function of water and the rotational pressure applied on the blades thereby generating results of the analysis using CFD post and plotted on a table for the comparative study of the blade models; and
manufacturing Kaplan turbine blade based on comparative study of the blade models using a machine learning approach through a manufacturing unit.

7. The method as claimed in claim 6, wherein the set of parameters are kept constant throughout the model designing to enable a constant mode of comparison between the different models of the turbine blades.

8. The method as claimed in claim 6, wherein comparative study comprising steps of:
obtaining data from the analysis and setting up in a spreadsheet user interface to obtain the desired graphical representation of the comparative study, wherein the study includes the graphical representation of how the efficiency and power of the blades vary with the flow rate; and
showing graphs on a display to show that the best model design that gives the maximum computational efficiency and power, wherein a pressure ratio variation is plotted with respected to the blade torque, rotation and the last plot is made for the variation in the power of the blades with respect to the flow rate of the water, wherein the Flow rate depends on a few factors like height of the water source and the turbulence it has.
